(19) United States
(12) Patent Application Publication
(10) Pub. No.: US 2025/0112113 A1
(43) Pub. Date: Apr. 3, 2025

(54) SYSTEMS AND METHODS FOR IMPROVING EMBEDDED SUBSTRATE THERMALS

(71) Applicant: Advanced Micro Devices, Inc., Santa Clara, CA (US)

(72) Inventors: Sriram Chandrasekaran, Austin, TX (US); Hemanth Kumar Dhavaleswarapu, Austin, TX (US); Robert Grant Spurney, Austin, TX (US)

(73) Assignee: Advanced Micro Devices, Inc., Santa Clara, CA (US)

(21) Appl. No.: 18/476,991

(22) Filed: Sep. 28, 2023

(51) Int. Cl. H01L 23/373; H01L 23/00; H01L 23/367; H01L 23/498

(52) U.S. Cl. CPC H01L 23/3735; H01L 23/3675; H01L 23/49822; H01L 24/16; H01L 24/32; H01L 2224/16146; H01L 2224/16235; H01L 2224/32146; H01L 2224/32235; H01L 2924/01029; H01L 2924/351

(57) ABSTRACT

A method can include embedding one or more thermal sources in a semiconductor package substrate and positioning one or more substrate buildup layers above the one or more thermal sources. The method can also include forming one or more thermal vias in the one or more substrate buildup layers. Various other methods and systems are also disclosed.

### BACKGROUND

A semiconductor package can be a casing (e.g., metal, plastic, glass, or ceramic) containing one or more discrete semiconductor devices or integrated circuits. Individual components can be fabricated on semiconductor wafers (e.g., silicon) before being diced into die, tested, and packaged. The package can provide one or more features for connecting the devices or circuits to an external environment (e.g., a printed circuit board) via leads (e.g., lands, balls, or pins). The package can additionally provide protection against threats such as mechanical impact, chemical contamination, and light exposure. The package can also help dissipate heat produced by the device or circuit, with or without the aid of a heat spreader. A package substrate can be made of a rigid material (e.g., ceramic, glass, etc.) to provide rigidity and protection to the device or circuit. Generally, a substrate can be positioned at a bottom of the package and a heat spreader can be positioned at a top of the package to dissipate rising heat.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a flow diagram of an example method for improving embedded substrate thermals.

FIG. 2 is a block diagram of an example semiconductor device package having improved embedded substrate thermals.

FIG. 3 is a block diagram of an example upper portion of a semiconductor device package substrate having improved embedded substrate thermals.

Throughout the drawings, identical reference characters and descriptions indicate similar, but not necessarily identical, elements. While the examples described herein are susceptible to various modifications and alternative forms, specific implementations have been shown by way of example in the drawings and will be described in detail herein. However, the example implementations described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to improving embedded substrate thermals. For example, by embedding one or more thermal sources in a semiconductor package substrate, positioning one or more substrate buildup layers above the one or more thermal sources, and forming one or more thermal vias in the one or more substrate buildup layers, a semiconductor device package with an embedded substrate can have improved thermals.

Benefits realized by the disclosed systems and methods can include reduction (e.g., approximately by 10% to 15%) in peak temperature of thermal sources, such as devices (e.g., integrated voltage regulators, capacitors, etc.), embedded in a package substrate. Reducing the peak temperature of such embedded devices can prevent thermal runaway and mitigate embedded device performance issues caused by temperature-based throttling. Another benefit can be a capability to isolate the dedicated thermal pathway from other substrate buildup layers, thus reducing the impact of Joule heating on embedded device temperatures.

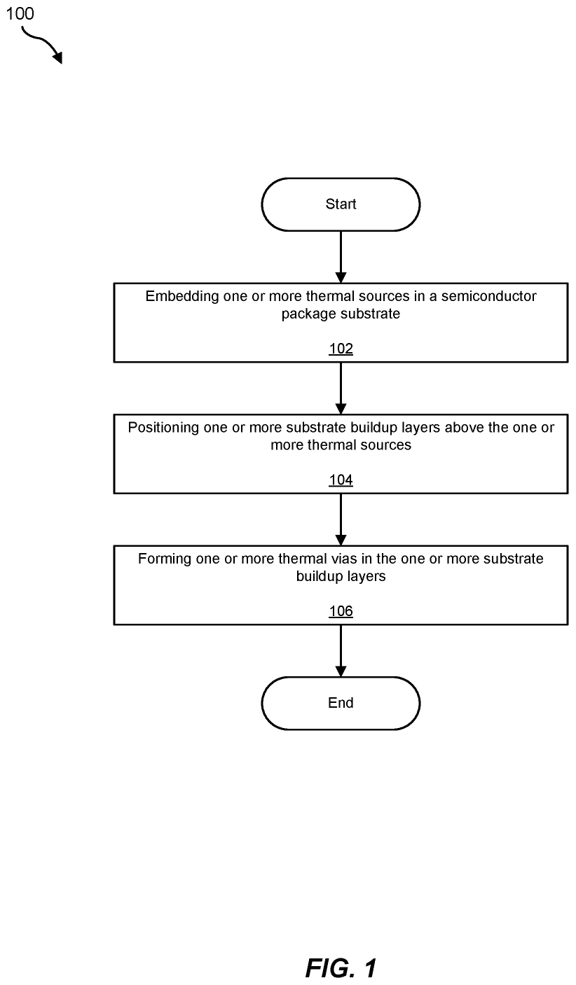

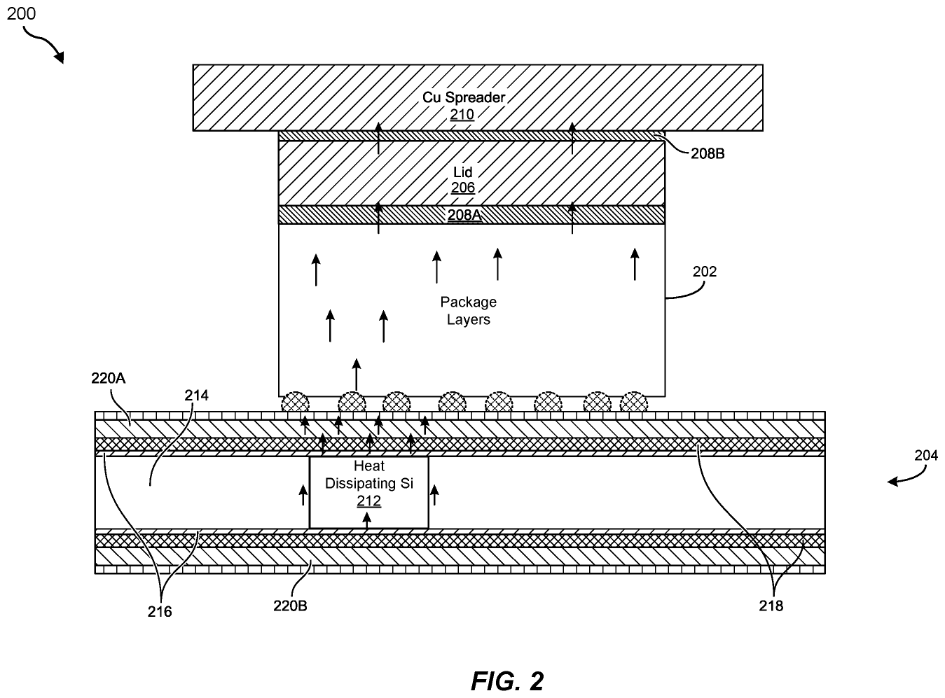

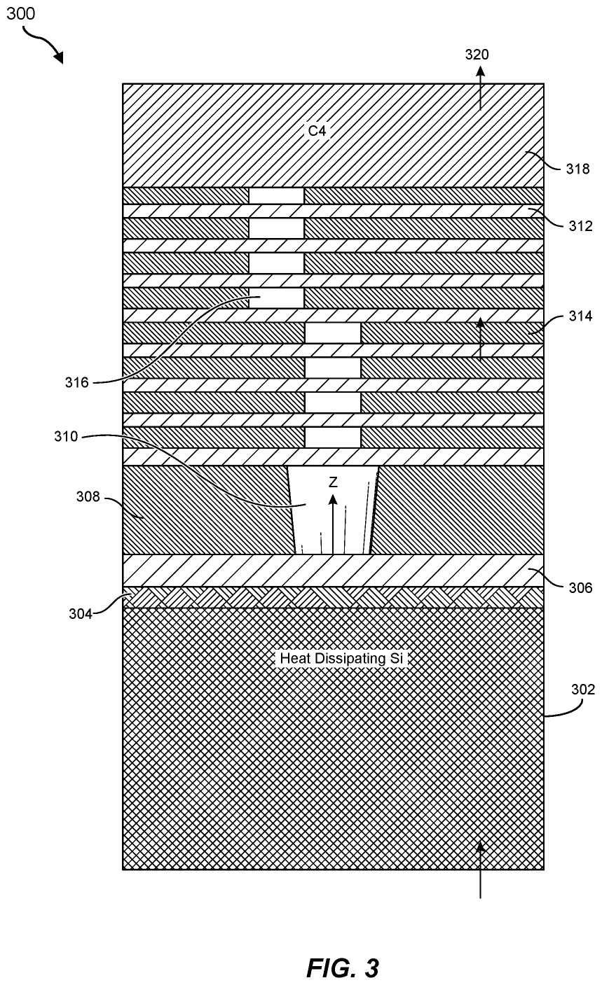

The following will provide, with reference to FIG. 1, an example method for improving embedded substrate thermals. In addition, detailed descriptions of example semiconductor device packages having improved embedded substrate thermals will be provided in connection with FIG. 2. Also, detailed descriptions of example upper portions of semiconductor device package substrates having improved embedded substrate thermals will be provided in connection with FIG. 3.

In one example, a semiconductor package substrate can include one or more thermal sources embedded in the semiconductor package substrate, one or more substrate buildup layers positioned above the one or more thermal sources, and one or more thermal vias formed in the one or more substrate buildup layers.

Another example can be the previously described example semiconductor package substrate, wherein the one or more thermal vias land on the one or more thermal sources.

Another example can be any the previously described example semiconductor package substrates, wherein the one or more thermal vias include a plurality of stacked thermal vias.

Another example can be the previously described example semiconductor package substrate, wherein the one or more thermal vias include two or more pluralities of stacked vias that are offset from one another.

Another example can be the previously described example semiconductor package substrate, wherein the one or more substrate buildup layers include a plurality of substrate buildup layers having one or more perforated copper layers positioned therebetween.

Another example can be the previously described example semiconductor package substrate, wherein the one or more thermal sources include an integrated voltage regulator.

Another example can be the previously described example semiconductor package substrate, wherein the one or more thermal sources include a capacitor.

In one example, semiconductor package can include a semiconductor device, a heat spreader positioned above the semiconductor device, and a substrate positioned below the semiconductor device, wherein the substrate includes one or more thermal sources embedded therein and one or more substrate buildup layers positioned above the one or more thermal sources and having one or more thermal vias formed therein.

Another example can be the previously described example semiconductor package, wherein the one or more thermal vias land on the one or more thermal sources.

Another example can be any of the previously described example semiconductor packages, wherein the one or more thermal vias include a plurality of stacked thermal vias.

Another example can be any of the previously described example semiconductor packages, wherein the one or more thermal vias include two or more pluralities of stacked vias that are offset from one another.

Another example can be any of the previously described example semiconductor packages, wherein the one or more substrate buildup layers include a plurality of substrate buildup layers having one or more perforated copper layers positioned therebetween.

Another example can be any of the previously described example semiconductor packages, wherein the one or more thermal sources include an integrated voltage regulator.

Another example can be any of the previously described example semiconductor packages, wherein the one or more thermal sources include a capacitor.

In one example, a method can include embedding one or more thermal sources in a semiconductor package substrate, positioning one or more substrate buildup layers above the one or more thermal sources, and forming one or more thermal vias in the one or more substrate buildup layers.

Another example can be the previously described example method, wherein the one or more thermal vias land on the one or more thermal sources.

Another example can be any of the previously described example methods, wherein the one or more thermal vias include a plurality of stacked thermal vias.

Another example can be any of the previously described example methods, wherein the one or more thermal vias include two or more pluralities of stacked vias that are offset from one another.

Another example can be any of the previously described example methods, wherein the one or more thermal sources include an integrated voltage regulator.

Another example can be any of the previously described example methods, wherein the one or more thermal sources include a capacitor.

FIG. 1 is a flow diagram of an example method 100 for improving embedded substrate thermals. As illustrated in FIG. 1, at step 102 one or more of the systems described herein can embed one or more thermal sources. For example, step 102 can include embedding one or more thermal sources in a semiconductor package substrate.

The term “embed,” as used herein, can generally refer to fixing an object in a surrounding mass. For example, and without limitation, embedding can include fixing a thermal source in a core material of a semiconductor package substrate.

The term “thermal source,” as used herein, can generally refer to an object that produces heat. For example, and without limitation, a thermal source can be a capacitor or an integrated voltage regulator.

The term “semiconductor package substrate,” as used herein, can generally refer to a component of a semiconductor package positioned at or near a bottom of the package. For example, and without limitation, a semiconductor package substrate can be made of a rigid material (e.g., ceramic, glass, etc.) that provides rigidity and protection to a semiconductor device or circuit.

The systems described herein can perform step 102 in a variety of ways. In one example, the one or more thermal sources can include an integrated voltage regulator. Additionally or alternatively, the one or more thermal sources can include a capacitor. In some examples, the one or more thermal sources can be embedded in a package substrate by placing them inside of substrate core material having plated through holes (PTHs) formed therein and atop a copper layer in a lower portion of the substrate. In some of these examples, the one or more thermal sources can be embedded in a package substrate by placing an additional copper layer atop the one or more thermal sources. Additionally or alternatively, a pre-impregnated fabric (prepreg) can be placed atop the additional copper layer in some of these examples.

At step 104, one or more of the systems described herein can position one or more substrate buildup layers. For example, step 104 can include positioning one or more substrate buildup layers above the one or more thermal sources.

The term “substrate buildup layers,” as used herein, can generally refer to a multilayer structure that is built up using thin films of copper and dielectric material. For example, and without limitation, substrate buildup layers can include layers of perforated copper alternately layered with layers of dielectric material. In this context, the term “perforated copper” can refer to copper layers that are perforated to form traces so that a portion of the copper layers can provide electrical connections while another portion of the copper layers can be electrically isolated from the traces.

The term “above,” as used herein, can generally refer to a position at a higher level or layer with respect to a gravity vector. For example, and without limitation, substrate buildup layers can be positioned above one or more thermal sources both during manufacture and during operation. Alternatively, substrate buildup layers can be positioned below one or more thermal sources during manufacture and later flipped to position the substrate buildup layers above the one or more thermal sources during operation. Thus, positioning above the one or more thermal sources can be accomplished in any manner that causes the substrate buildup layers to be positioned above the one or more thermal sources during operation.

The systems described herein can perform step 104 in a variety of ways. In one example, one or more substrate buildup layers (e.g., dielectric material) can be placed atop a pre-impregnated fabric and/or additional copper layer. Additionally or alternatively, the one or more substrate buildup layers can include a plurality of substrate buildup layers (e.g., dielectric material) having one or more perforated copper layers positioned therebetween. In some of these examples, positioning the one or more substrate buildup layers can include alternately depositing layers of dielectric material and layers of perforated copper.

At step 106, one or more of the systems described herein can form one or more thermal vias. For example, step 106 can include forming one or more thermal vias in the one or more substrate buildup layers.

The term “form,” as used herein, can generally refer to making or fashioning a material into a certain shape or form and/or bringing together or combining parts in order to create something. For example, and without limitation, forming of thermal vias can occur by making or fashioning films of dielectric material with through holes and/or material (e.g., copper) having a higher thermal conductivity than the dielectric material.

The term “thermal vias,” as used herein, can generally refer to a thermally conductive path in a layer of material, wherein the path has a lower thermal conductivity than the layer of material. For example, and without limitation, a thermal via can be a hole formed in a layer of thermally insulating material (e.g., dielectric material), and the hole can be plated with a thermally conductive material (e.g., metal, copper, etc.). In this context, the term “dedicated thermal via,” as used herein, can refer to a via that is not used for electrical connection, but that functions as a thermal pathway.

The systems described herein can perform step 106 in a variety of ways. In one example, the one or more thermal vias can land on the one or more thermal sources. Additionally or alternatively, the one or more thermal vias can include a plurality of stacked thermal vias. Additionally or alternatively, the one or more thermal vias can include two or more pluralities of stacked thermal vias that are offset (e.g., laterally) from one another. For example, a number (e.g., eight or less, four or less, etc.) of stacked thermal vias can be formed atop one another in layers of dielectric material included in the substrate buildup layers, and another number (e.g., eight or less, four or less, etc.) of stacked vias can be formed atop one another in other layers of dielectric material included in the substrate buildup layers. These stacked vias can be offset from one another to improve structural integrity of the substrate buildup layers while a perforated copper layer positioned between the stacked vias can provide thermal conductivity between the offset stacks of thermal vias. In some examples, the thermal vias (e.g., stacked thermal vias) can be dedicated thermal vias that are not used for electrical connectivity. Thus, the thermal vias can connect perforated copper layers that are electrically isolated from portions of the copper layers used for traces, thus avoiding shorting any electrical connections. In some examples, the thermal vias can be through holes. Additionally or alternatively, the thermal vias can be formed of a material (e.g., copper) having a higher thermal conductivity than that of the dielectric material included in the substrate buildup layers.

FIG. 2 illustrates an example semiconductor device package 200 having improved embedded substrate thermals. For example, a semiconductor device 202 can be positioned atop a package substrate 204 and covered by a lid 206, thermal interface material 208A and 208B, and a (e.g., copper) heat spreader 210 arranged as shown. Additionally, one or more thermal sources 212, such as a capacitor, an integrated voltage regulator (IVR silicon) having mutual inductors (MCU), and/or any other heat dissipating silicon, can be embedded in a core material 214 of the substrate, and this core material 214 can have plated through holes (PTHs) formed therein. The core material 214 can be sandwiched between copper layers 216, pre-impregnated fabric 218 having micro vias, and substrate buildup layers, such as top substrate buildup layers 220A and bottom substrate buildup layers 220B. These substrate buildup layers can have shadow masks facilitating electrical connection to, for example, C4 bumps.

Thermal energy produced by the one or more thermal sources 212 can rise through a top one of copper layers 216 and micro vias of a top layer of pre-impregnated fabric 218 to the top substrate buildup layers 220A, which can contain layers of perforated copper and dielectric material. The thermal energy can pass through the top substrate buildup layers 220A and shadow mask to C4 bumps connecting the semiconductor device 202 to the substrate 204. Thermal pathways in the semiconductor device 202 can transfer the thermal energy upwards from the C4 bumps to thermal interface material 208A and 208B, lid 206, and heat spreader 210 for thermal dissipation. However, while perforated copper layers of the top substrate buildup layers 220A can efficiently transfer the thermal energy, layers of dielectric material in the top substrate buildup layers 220A are less efficient at affecting thermal energy transfer.

Addition of dedicated thermal vias in the dielectric material of the top substrate buildup layers 220A can improve embedded substrate thermals. For example, the top substrate buildup layers 220A can have stacked thermal vias in its dielectric layers at one or more locations that do not require electrical connectivity. Thus, perforated copper layers in the one or more locations can be electrically isolated from portions of the copper layers used for traces, and the stacked thermal vias can avoid shorting any electrical connections. These stacked thermal vias can land on a top side of the one or more thermal sources 212 (e.g., on the heat dissipating silicon). The stacked thermal vias can be through holes or can be a material (e.g., copper) that has a higher thermal conductivity than that of the dielectric material included in the substrate buildup layers. Individual stacks of vias can include a number (e.g., eight or less, four or less, etc.) of stacked vias and be offset laterally from one another while contacting a same perforated copper layer that can facilitate thermal energy transfer between the laterally offset stacks. Limiting the number of vias in a stack and offsetting stacks in this manner can aid in maintaining structural integrity of the top substrate buildup layers 220A.

FIG. 3 illustrates an example upper portion 300 of a semiconductor device package substrate having improved embedded substrate thermals. For example, a top side of a thermal source 302 (e.g., heat dissipating silicon) can contact a backside metallization layer 304 positioned in contact with a copper layer 306 arranged as shown. Additionally, pre-impregnated fabric 308 having one or more micro vias 310 formed therein can contact the copper layer 306. Together, the one or more micro vias 310, copper layer 306, and backside metallization layer 304 can land on the top side of the thermal source 302. Also, substrate buildup layers can contact the pre-impregnated fabric 308 having one or more micro vias 310 formed therein. The substrate buildup layers can include perforated copper layers 312 alternately layered with layers of dielectric material 314.

Addition of dedicated thermal vias 316 in the layers of dielectric material 314 can improve embedded substrate thermals. For example, stacked thermal vias 316 can be provided in the layers of dielectric material 314 at one or more locations that do not require electrical connectivity. Thus, perforated copper layers 312 in the one or more locations can be electrically isolated from portions of the perforated copper layers 312 used for traces, and the stacked thermal vias 316 can avoid shorting any electrical connections. These stacked thermal vias 316 can land on a top side of the thermal source 302 by landing on the one or more micro vias 310 formed on the pre-impregnated fabric above the thermal source 302. The stacked thermal vias 316 can be through holes or can be a material (e.g., copper) that has a higher thermal conductivity than that of the layers of dielectric material 314. Individual ones of the stacked thermal vias 316 can contact perforated copper layers 312 immediately above and below the individual thermal via. Individual stacks of vias can include a number (e.g., eight or less, four or less, etc.) of stacked vias and be offset laterally from one another while contacting a same perforated copper layer that can facilitate thermal energy transfer between the laterally offset stacks. Limiting the number of vias in a stack and offsetting stacks in this manner can aid in maintaining structural integrity of the layers of dielectric material 314.

Thermal energy produced by the thermal source 302 can rise through the backside metallization layer 304, the copper layer 306, the one or more micro vias 310, the perforated copper layers 312, and the stacked thermal vias 316 to C4 bumps 318. Heat transfer 320 can occur from the C4 bumps 318 through the semiconductor device to a heat sink for thermal dissipation. The addition of the stacked thermal vias in the layers of dielectric material of the substrate buildup layers in the upper portion 300 of a semiconductor device package can improve the embedded substrate thermals significantly.

As set forth above, by embedding one or more thermal sources in a semiconductor package substrate, positioning one or more substrate buildup layers above the one or more thermal sources, and forming one or more thermal vias in the one or more substrate buildup layers, a semiconductor device package with an embedded substrate can have improved thermals. For example, peak temperature of thermal sources, such as devices (e.g., integrated voltage regulators, capacitors, etc.), embedded in a package substrate can be reduced (e.g., approximately by 10% to 15%). Reducing the peak temperature of such embedded devices can prevent thermal runaway and mitigate embedded device performance issues caused by temperature-based throttling. Another benefit can be a capability to isolate the dedicated thermal pathway from other substrate buildup layers, thus reducing the impact of Joule heating on embedded device temperatures.

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor package substrate, comprising:
one or more thermal sources embedded in the semiconductor package substrate;
one or more substrate buildup layers positioned above the one or more thermal sources; and
one or more thermal vias formed in the one or more substrate buildup layers.

2. The semiconductor package substrate of claim 1, wherein the one or more thermal vias land on the one or more thermal sources.

3. The semiconductor package substrate of claim 1, wherein the one or more thermal vias include a plurality of stacked thermal vias.

4. The semiconductor package substrate of claim 1, wherein the one or more thermal vias include two or more pluralities of stacked vias that are offset from one another.

5. The semiconductor package substrate of claim 1, wherein the one or more substrate buildup layers include a plurality of substrate buildup layers having one or more perforated copper layers positioned therebetween.

6. The semiconductor package substrate of claim 1, wherein the one or more thermal sources include an integrated voltage regulator.

7. The semiconductor package substrate of claim 1, wherein the one or more thermal sources include a capacitor.

8. A semiconductor package, comprising:
a semiconductor device;
a heat spreader positioned above the semiconductor device; and
a substrate positioned below the semiconductor device, wherein the substrate includes one or more thermal sources embedded therein and one or more substrate buildup layers positioned above the one or more thermal sources and having one or more thermal vias formed therein.

9. The semiconductor package of claim 8, wherein the one or more thermal vias land on the one or more thermal sources.

10. The semiconductor package of claim 8, wherein the one or more thermal vias include a plurality of stacked thermal vias.

11. The semiconductor package of claim 8, wherein the one or more thermal vias include two or more pluralities of stacked vias that are offset from one another.

12. The semiconductor package of claim 8, wherein the one or more substrate buildup layers include a plurality of substrate buildup layers having one or more perforated copper layers positioned therebetween.

13. The semiconductor package of claim 8, wherein the one or more thermal sources include an integrated voltage regulator.

14. The semiconductor package of claim 8, wherein the one or more thermal sources include a capacitor.

15. A method comprising:
embedding one or more thermal sources in a semiconductor package substrate;
positioning one or more substrate buildup layers above the one or more thermal sources; and
forming one or more thermal vias in the one or more substrate buildup layers.

16. The method of claim 15, wherein the one or more thermal vias land on the one or more thermal sources.

17. The method of claim 15, wherein the one or more thermal vias include a plurality of stacked thermal vias.

18. The method of claim 15, wherein the one or more thermal vias include two or more pluralities of stacked vias that are offset from one another.

19. The method of claim 15, wherein the one or more thermal sources include an integrated voltage regulator.

20. The method of claim 15, wherein the one or more thermal sources include a capacitor.
